(19) United States
(12) Patent Application Publication
(10) Pub. No.: US 2007/0007638 A1
(43) Pub. Date: Jan. 11, 2007

(54) MEMORY ARRAY MODULE MOUNTING STRUCTURE

(75) Inventor: Shih-Hsiung Lien, TAIPEI (TW)

Correspondence Address: OPTIMUM CARE INTERNATIONAL TECH. INC., P.O. BOX 108-00403, TAIPEI, TW

(73) Assignee: OPTIMUM CARE INTERNATIONAL TECH. INC., Taipei City (TW)

(21) Appl. No.: 11/308,161

(22) Filed: Mar. 9, 2006

(30) Foreign Application Priority Data
Jul. 6, 2005 (TW) 094122928

(51) Int. Cl. H01L 23/02

(52) U.S. Cl. 257/686

(57) ABSTRACT

A memory array module mounting structure is disclosed to include a main board, which has circuit contacts arranged thereon, a plurality of connectors installed in the main board and electrically connected to the circuit contacts of the main board, and a plurality of memory chips respectively detachably inserted into the connectors and kept electrically connected to the circuit contacts of the main board. Each memory chip can be removed from the respective connector for repair or replacement without reflow or desolder process when damaged.

This application claims the priority benefit of Taiwan patent application number 094122928 filed on Jul. 6, 2005.

### BACKGROUND OF THE INVENTION

1. Field of the Invention

The present invention relates to a memory array module and more particularly, to a memory array module mounting structure, which has a number of connectors arranged at a main board and a plurality of memory chips respectively detachably inserted into the connectors and kept electrically connected to respective circuit contacts of the main board. This design allows quick replacement of memory chips.

2. Description of the Related Art

Following fast development of high technology, a variety of sophisticated electronic products are created and intensively used in our daily life for different purposes. Among these electronic products, computer is the one that has an intimate relationship with our daily life. People can obtain various different informations from the Internet through a computer. A computer can help people handle paperwork, draw pictures, compute data, as well as transmit video and/or audio data to a remote place. A memory module is an important unit in a computer. Without this memory module, the computer cannot be boosted, and the peripheral apparatus cannot transmit data to the CPU. Simply speaking, the memory module of a computer is a communication medium between the CPU and the peripheral apparatus. The clock of the memory module can accelerate data transmission of the CPU and the peripheral apparatus. Increasing of bandwidth relatively increases data transmission capacity. Increasing memory capacity relatively increases data processing space. In order to meet the high operation and data processing speed of an advanced CPU, the clock, bandwidth and memory capacity of the memory module must be relatively improved.

Further, from the early design of 30-pin SIMM (single Inline Memory Module) to the modern design of DIMM and RDRAM RIMM of DDR specifications, the capacity of a memory module is formed of multiple individual memory chips. As shown in FIGS. 7 and 8, a memory module A according to the prior art design comprises a substrate A1, which has a set of contacts A11 (the so-called gold indexes), and a plurality of memory chips A2 soldered to the substrate A1. A main board B has slots B1 corresponding to the contacts A11 of the substrates A1 of the memory modules A, and retaining rods B11 at two sides of each slot B1 for securing the respective memory modules A to the respective slots B1. This design of memory module mounting arrangement has drawbacks as follows.

1. The memory chips A2 of each memory module A are soldered to the respective substrate A1. When one memory chip A2 fails, the respective memory module A must be disconnected from the respective slot B1, and then the pins of the damaged memory chip A2 must be desoldered from the substrate A1 so that the damaged memory chip A2 can be removed from the substrate A1 for replacement. During installation of a new memory chip A2, a reflow process is employed to bond the new memory chip A2 to the substrate A1. Because modern memory chips have light, thin, short and small characteristics, the pitch of the contact pins of the memory chips A2 is small. It is difficult to employ desolder or reflow process. During desolder or reflow process, the produced high temperature may damage the other memory chips A2.

2. Because the aforesaid desolder or reflow process must be performed by labor, the whole work is inconvenient to finish, and only specifically trained persons can do the job. Further, this method cannot eliminate human errors, resulting in many problems (such as false soldering, overhead, or contact error. All these problems greatly complicate the maintenance work and increase the maintenance cost.

3. The memory modules A and the computer main board B must be separately fabricated. However, the memory modules A must be compatible to the computer main board B. Because the processing of the computer main board B and the processing of the memory modules A are separately performed, the assembly cannot be made through an integral manufacturing flow, i.e., the fabrication of the assembly is complicated, requiring much manufacturing time.

### SUMMARY OF THE INVENTION

The present invention has been accomplished under the circumstances in view. It is the main object of the present invention to provide a memory array module mounting structure, which allows quick replacement of memory chips. To achieve this and other objects of the present invention, the memory array module mounting structure comprises a main board, which has a plurality of circuit contacts and electronic component parts arranged thereon, a plurality of memory chips for arranging on the main board, and a plurality of connectors respectively installed in the main board and electrically connected to the circuit contacts of the main board for detachably receiving the memory chips to hold the memory chips electrically connected to the circuit contacts of the main board without soldering.

### BRIEF DESCRIPTION OF THE DRAWINGS

FIG. 1 is schematic block diagram of the present invention.

FIG. 2 is an elevational view of a memory array module mounting structure according to the present invention.

FIG. 3 is a sectional side view in an enlarged scale of a part of FIG. 2.

FIG. 4 is an elevational view of an alternate form of the memory array module mounting structure according to the present invention.

FIG. 4A is an enlarged view of a part of FIG. 4.

FIG. 5 is an elevational view of another alternate form of the memory array module mounting structure according to the present invention.

FIG. 6 is a side view in section in an enlarged scale of a part of FIG. 5.

FIG. 7 is a schematic block diagram of the prior art design.

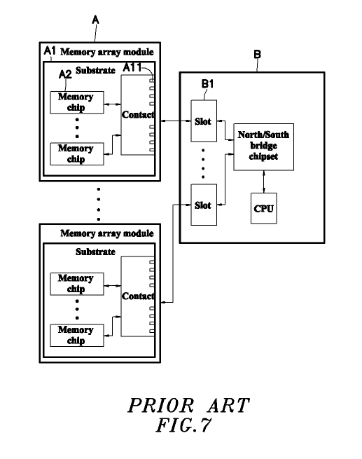

FIG. 8 is an elevational view of a memory chip module according to the prior art.

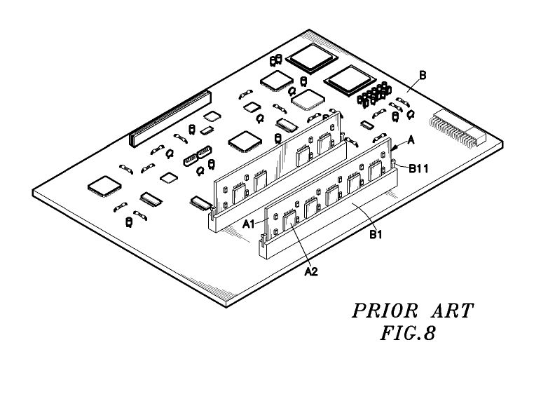

### DETAILED DESCRIPTION OF THE PREFERRED EMBODIMENT

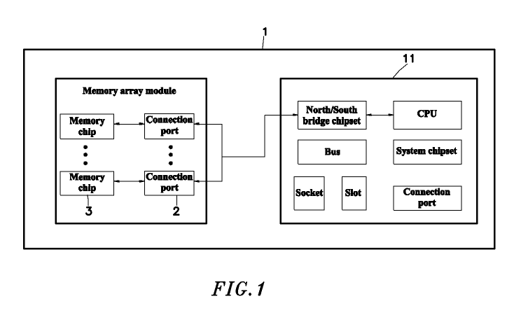

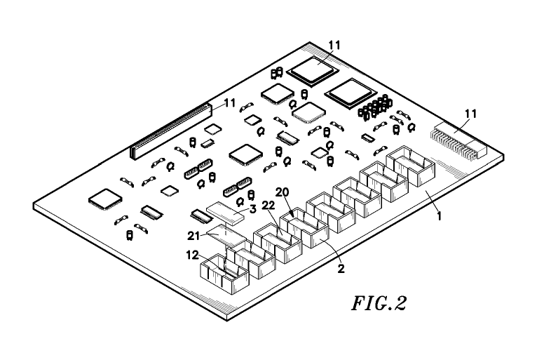

Referring to FIGS. 1 and 2, a memory array module mounting structure in accordance with the present invention is shown comprising a main board 1, which has arranged thereon circuit contacts 12 and related electronic component parts 11 that can be system chipset, CPU, bus, slot, socket, and/or connection port, a plurality of connectors 2 installed in the main board 1 for the positioning of memory chips 3 without welding, for enabling the memory chips 3 to be electrically connected to the circuit contacts 12 at the main board 1. When making the circuit contacts 12 at the main board 1 through a lithographic technology, the desired circuit contacts 12 for the connector 2 are simultaneously made at the main board 1, thereby simplifying the processing process of the main board 1 and effectively reduce the cost of the present invention.

If case one memory chip 3 fails during the use of the main board 1, the failed memory chip 3 can be directly pulled away from the respective connector 2 for repair or replacement.

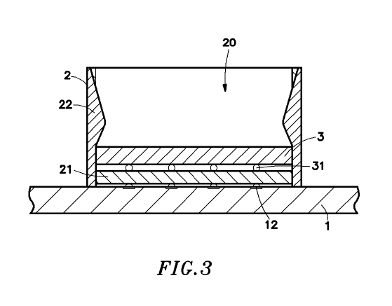

Referring to FIG. 3 and FIG. 2 again, the connector 2 is a hollow member defining therein an accommodating chamber 20. Further, the connector 2 has positioning means 22 provided inside the accommodating chamber 20 for holding down the inserted memory chip 3 in position. Further, a conducting medium 21 is mounted in the accommodating chamber 20 and kept in contact with respective circuit contact 12 at the main board 1. The memory chip 3 has a plurality of circuit contacts 31 at the bottom side. After insertion of the memory chip 3 into the accommodating chamber 20, the positioning means 22 holds down the memory chip 3 in the accommodating chamber 20, keeping the circuit contacts 31 of the memory chip 3 pressed on the conducting medium 21 against the respective circuit contacts 12 at the main board 1. By means of the vertical transmission electric characteristic of the conducting medium 21, the memory chip 3 is electrically connected to the main board 1. If the memory chip 3 fails, the user can directly remove the memory chip 3 out of the accommodating chamber 20 of the connector 2 for repair or replacement. Further, the circuit contacts 31 of the memory chip 3 can be solder balls, solder pads, copper foils, metal lead frames, or other proper metal conducting materials. Further, the conducting medium 21 can be an anisotropic conductive film material formed of a resin and a conducting powder.

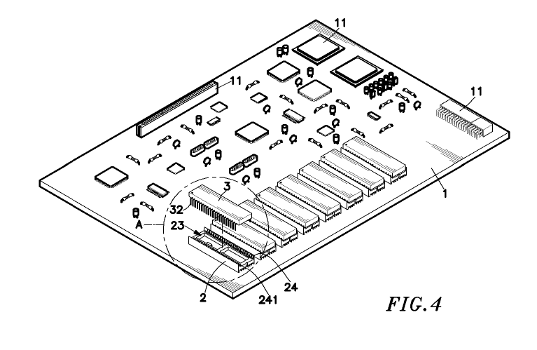

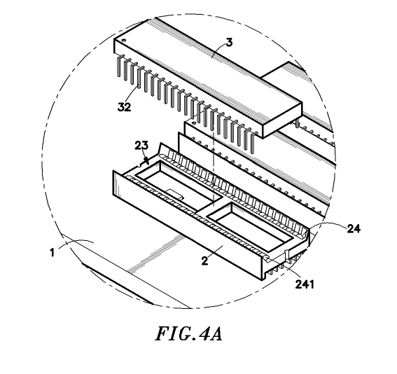

FIGS. 4 and 4A show an alternate form of the present invention. According to this embodiment, a plurality of connectors 2 are installed in a main board 1 for receiving a respective memory chip 3. Each connector 2 has a top accommodating chamber 23, a plurality of plugholes 24 arranged in line at two opposite lateral sides of the top accommodating chamber 23, and a plurality of terminals 241 respectively mounted in the plugholes 24 and electrically connected to respective circuit contacts 12 at the main board 1. The memory chip 3 has a plurality of downward pins 32 arranged at two sides and respectively inserted into the plugholes 24 and kept in contact with the respective terminals 241 in the plugholes 24. Therefore the memory chip 3 is electrically connected to the main board 1. In case the memory chip 3 fails, it can be directly removed from the respective connector 2 for repair of replacement.

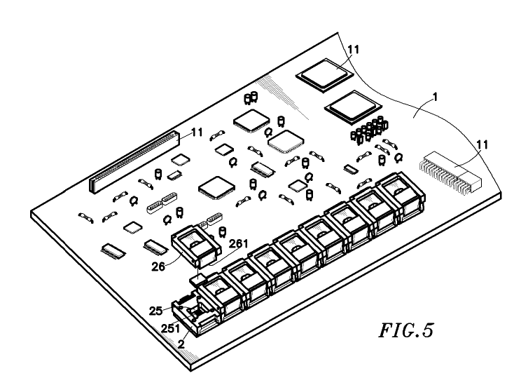

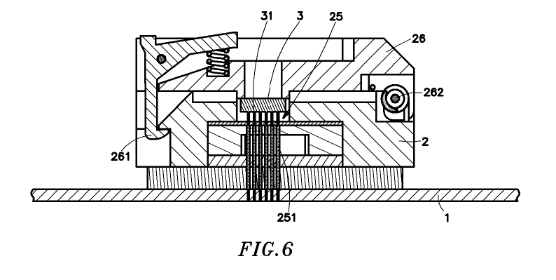

FIGS. 5 and 6 show another alternate form of the present invention. According to this embodiment, each connector 2 has a positioning hole 25 for receiving one memory chip 3 and a plurality of terminals 251 installed in the positioning hole 25 and respectively electrically connected to respective circuit contacts 12 at the main board 1. Further, a cover 26 is pivotally connected to one side of each connector 2 by a hinge 262 for closing the positioning hole 25 after installation of one memory chip 3 in the positioning hole 25. The cover 26 has a hook 261 at the free end for hooking on a part of the respective connector 2 to secure the cover 26 to the respective connector 2 in the closed position. When the cover 26 is locked in the closed position after insertion of the memory chip 3 in the positioning hole 25, the cover 26 holds down the memory chip 3, keeping the bottom of the cover 26 in contact with the top of the memory chip 3 and the bottom circuit contacts 31 in contact with the terminals 251 in the positioning hole 25 respectively, and therefore the memory chip 3 is kept electrically connected to the main board 1. In case the memory chip 3 fails, the user can open the cover 26 of the respective connector 2 and remove the memory chip 3 out of the respective connector 2 for repair or replacement.

In general, the invention has a plurality of connectors 2 provided at a main board 1 for receiving memory chips 3, keeping the memory chips 3 electrically connected to the main board 1 without welding. In case one memory chip 3 fails, the damaged memory chip 3 can be directly removed from the respective connector 2 for repair or replacement.

As indicated above, the invention provides a memory array module, which has the following features.

1. Memory chips 3 are detachably installed in the connectors 2 at the main board 1 and electrically connected to the main board 1 through the connectors 2. The memory chips 3 can be directly removed from the respective connectors 2 for repair or replacement without high-temperature reflow or desolder process. When a new memory chip 3 is inserted into the respective connector 2, it is automatically connected to the respective circuit contacts 12 at the main board 1, and the main board 1 can be re-boosted immediately. This design facilitates the maintenance work. The repair engineer can start the repair work without special training.

2. Because it is not necessary to perform a reflow or desolder process when removing one memory chip 3 from the respective connector 2 for repair or replacement, the maintenance work can easily be performed without causing damage to the circuit contacts 12 of the main board 1 or the electronic component parts 11 at the main board 1.

3. When making circuit contacts 12 at the main board 1 through a lithographic technology, the desired circuit contacts 12 for the designed connectors 2 are simultaneously made at the main board 1, and the connectors 2 are respectively soldered to the respective circuit contacts 12 at the same time during installation of the electronic component parts 11 in the main board 1. Therefore, the total processing process of the main board 1 is simplified, improving the yielding rate and reducing the manufacturing cost.

4. The invention eliminates the drawback of the prior art designs that a different type of memory chip must fits a different main board, and therefore the invention saves much main board material and main board processing cost.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A memory array module mounting structure comprising:
a main board, said main board having a plurality of circuit contacts and electronic component parts thereon;
a plurality of memory chips for arranging on said main board; and
a plurality of connectors respectively installed in said main board and electrically connected to the circuit contacts of said main board for detachably receiving said memory chips to hold said memory chips electrically connected to the circuit contacts of said main board.

2. The memory array module mounting structure as claimed in claim 1, wherein said electronic component parts of said main board include at least one system chipset, one central processing unit, one bus, one slot, one socket and one connection port.

3. The memory array module mounting structure as claimed in claim 1, wherein said connectors each is a hollow member defining therein an accommodating chamber for accommodating one of said memory chips, and a conducting medium mounted in said accommodating chamber for supporting said respective memory chip on said respective circuit contacts of said main board.

4. The memory array module mounting structure as claimed in claim 3, wherein said memory chips each have a bottom side and a plurality of circuit contacts arranged at said bottom side thereof and pressed on said conducting medium in said respective connector against said respective circuit contacts of said main board to form a vertical transmission electric connection.

5. The memory array module mounting structure as claimed in claim 4, wherein said circuit contacts of said memory chips are metal contact means selected from electrically conductive materials including solder balls, solder pads, copper foils, and metal lead frames.

6. The memory array module mounting structure as claimed in claim 4, wherein said conducting medium is an anisotropic conductive film material formed of a resin and a conducting powder.

7. The memory array module mounting structure as claimed in claim 1, wherein said connectors each comprises a plurality of plugholes and a plurality of terminals respectively mounted in said plugholes and respectively electrically connected to said circuit contacts of said main board; said memory chips each have a plurality of downward pins for insertion into said plugholes of said connectors into contact with said terminals of said respective connector.

8. The memory array module mounting structure as claimed in claim 1, wherein said connectors each have a plurality of terminals respectively electrically connected to said circuit contacts of said main board; said memory chips each have a bottom side and a plurality of circuit contacts at the bottom side for contacting said terminals of said connectors.
